(19) United States
(12) Patent Application Publication
(10) Pub. No.: US 2006/0138639 A1
(43) Pub. Date: Jun. 29, 2006

(54) Capacitor pad network to manage equivalent series resistance

(76) Inventors: David G. Figueroa, Tolleson, AZ (US); Jennifer A. Hester, Litchfield Park, AZ (US); Yuan-Liang Li, Chandler, AZ (US)

Correspondence Address: Buckley, Maschoff & Talwalkar LLC, Attorneys for INTEL Corporation, Five Elm Street, New Canaan, CT, 06840, US

(21) Appl. No.: 11/024,059

(22) Filed: Dec. 28, 2004

(51) Int. Cl. H01L 23/12

(52) U.S. Cl. 257/700

(57) ABSTRACT

According to some embodiments, an apparatus includes a first conductive pad, a first conductive plane, first dielectric material disposed between the first conductive plane and the first conductive pad, a second conductive plane, second dielectric material disposed between the first conductive plane and the second conductive plane, and a first conductive network. The first conductive network includes a first microvia within the first dielectric material and coupled to the first conductive pad, a first conductive trace within the first conductive plane and coupled to the first microvia, a second microvia within the second dielectric material and coupled to the first conductive trace, a second conductive trace within the second conductive plane and coupled to the second microvia, a third microvia within the second dielectric material and coupled to the second conductive trace, a third conductive trace within the first conductive plane and coupled to the third microvia, and a fourth microvia within the second dielectric material and coupled to the third conductive trace.

### BACKGROUND

An integrated circuit package may route electrical signals between an integrated circuit die and a substrate to which the package is mounted. These signals often result in unwanted resonance, which may negatively affect the performance of the integrated circuit die. Decoupling capacitors may be mounted on an integrated circuit package in order to address this resonance.

FIG. 1 is a cutaway side view of a conventional integrated circuit package showing the electrical connection of a decoupling capacitor thereto. Package 10 includes core 20, on which are disposed conductive planes 32 through 36 and layers 40 through 46 of dielectric material. Layer 46 supports conductive pads 50 and 60 for receiving terminals of capacitor 70.

Pad 50 is coupled to an electrical circuit through microvias 51, 53 and 55 and conductive traces 52, 54 and 56. In this regard, trace 56 may extend into conductive plane 32 and connect to unshown circuitry in plane 30 or on an opposite side of core 20. Similarly, pad 60 is coupled to an electrical circuit through microvias 61, 63, 65 and 67 and conductive traces 62, 64, 66 and 68. Conventional decoupling capacitors such as capacitor 70 may exhibit an Equivalent Series Resistance (ESR) that is unsuitable for some applications. For example, the ESR of a capacitor may be too low to satisfactorily dampen the aforementioned resonance.

### BRIEF DESCRIPTION OF THE DRAWINGS

FIG. 1 is a side cutaway view of a conventional integrated circuit package.

FIG. 2 is a side cutaway view of an integrated circuit package including an electrical network according to some embodiments.

FIG. 3 is a side cutaway view of an integrated circuit package including an electrical network according to some embodiments.

FIG. 4 is a flow diagram of a process to fabricate an apparatus according to some embodiments.

FIGS. 5A through 5G are side cutaway views of an integrated circuit package during fabrication according to some embodiments of the FIG. 4 process.

FIG. 6 is a bottom view of an integrated circuit package.

FIG. 7 is a cutaway side elevation of a system according to some embodiments.

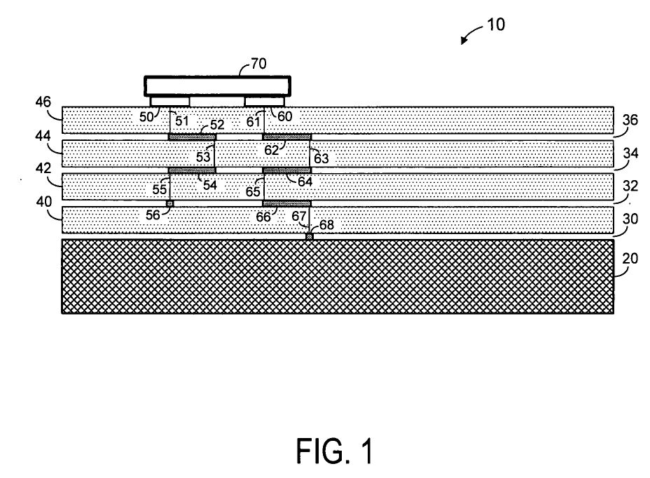

### DETAILED DESCRIPTION

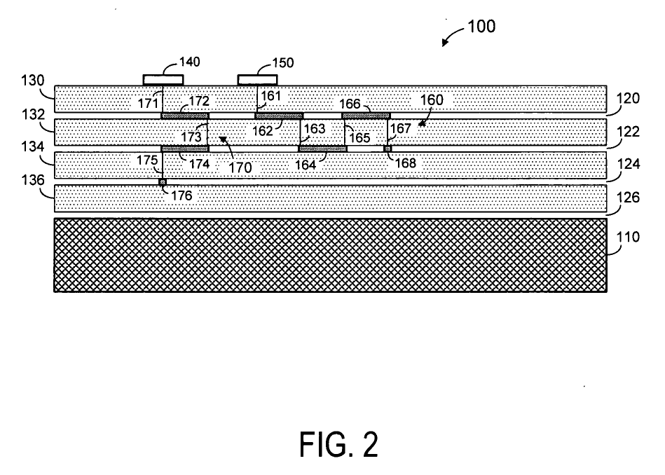

FIG. 2 is a cutaway side view of integrated circuit package 100 according to some embodiments. Integrated circuit package 100 may comprise any ceramic, organic, and/or other suitable material. Integrated circuit package 100 may be suitable for receiving an integrated circuit die and electrically coupling the integrated circuit die to external circuitry.

Integrated circuit package 100 includes core 110. Core 110 may be composed of any suitable material according to some embodiments, including but not limited to bismalemide triazine (BT) and FR4. Core 110 supports layers of conductive planes 120 through 126 that include conductive paths, or traces, for routing signals within integrated circuit package 100. The conductive traces may comprise copper or any other suitable conductive material.

Planes 120 through 126 are separated from one another by layers 130 through 136. Layers 130 through 136 may be composed of dielectric material and/or other material such as BT or FR4.

Conductive pads 140 and 150 may be suited to receive terminals of a capacitor (not shown). Conductive pads 140 and 150 electrically couple the capacitor to conductive elements of package 100. Conductive pads 140 and 150 may comprise metal-plated built-up pads, solder balls, or any conductive structure compatible with terminals to be received.

Conductive network 160 may be used to couple capacitor pad 150 to specific circuitry of package 100 and, in turn, to external circuitry and/or an integrated circuit die. Conductive network 160 includes microvia 161 within dielectric material layer 130. Generally, a microvia may electrically couple conductive elements that are disposed in different conductive planes of an integrated circuit package. Microvia 161 couples conductive pad 150 to conductive trace 162 of conductive plane 120.

Conductive trace 162 may or may not be electrically coupled to other conductive traces or elements within conductive plane 120. As shown in FIG. 2, conductive trace 162 is coupled to microvia 163 of layer 132. Microvia 163 is also coupled to conductive trace 164 of conductive layer plane 122.

An electrical signal passing through elements 161, 162, 163 and 164 returns to conductive plane 120 through microvia 165. Microvia 165 is coupled to conductive trace 166 of plane 120, which is in turn coupled to microvia 167. Microvia 167 is also coupled to conductive trace 168 of plane 122. Conductive trace 168 may extend into conductive plane 122 and be coupled to other planes within integrated circuit package 100 which eventually connect to external circuitry and/or to an integrated circuit die coupled to package 100.

Network 160 may effectively increase the ESR of a capacitor coupled to conductive pads 140 and 150. The increased ESR may reduce resonance during operation of a system including package 100. According to some embodiments, network 160 may allow the use of a capacitor having a lower ESR than would be required in the absence of network 160. The individual elements of network 160 may be designed and fabricated so as to provide a particular desired ESR. In some embodiments, a majority of the additional ESR attributable to network 160 is provided by conductive traces 162, 164, 166 and 168.

Network 170 may also couple capacitor pad 140 to other circuitry. Network 170 includes microvia 171 within dielectric material layer 130. Microvia 171 couples conductive pad 140 to conductive trace 172 of conductive plane 120. Conductive trace 172 is in turn coupled to microvia 173 of layer 132. Microvia 173 is also coupled to conductive trace 174 of conductive layer plane 122. Microvia 175 is coupled to conductive trace 174 and to conductive trace 176 of plane 122. Conductive trace 176 may extend into conductive plane 134 and be coupled to other planes within integrated circuit package 100 which eventually connect to external circuitry and/or to an integrated circuit die.

Some embodiments include one or more additional conductive pads for receiving additional terminals of a capacitor that is coupled to pads 140 and 150. Any of the one or more additional conductive pads may be coupled to a network such as network 160 or network 170.

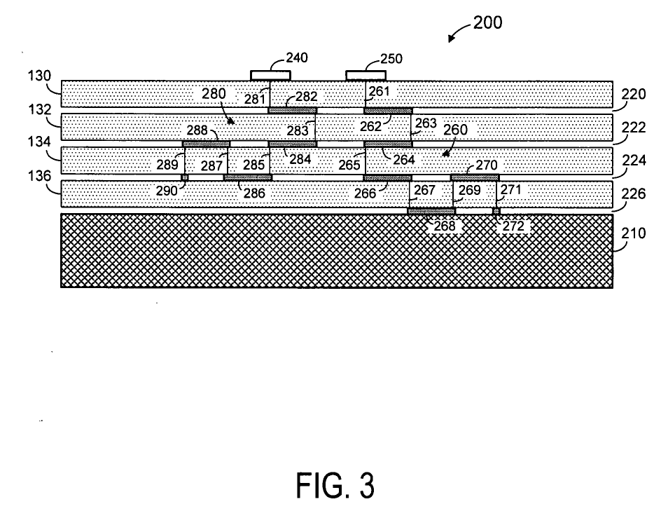

FIG. 3 is a cutaway side view of integrated circuit package 200 according to some embodiments. Integrated circuit package 200 includes core 210, conductive planes 220 through 226, and dielectric layers 230 through 236, which may be arranged similarly to corresponding structures of integrated circuit package 200.

Conductive pads 240 and 250 are for electrically coupling terminals of a capacitor to conductive elements of package 200. More specifically, conductive pad 240 is coupled to conductive network 280 and conductive pad 250 is coupled to conductive network 260. Networks 260 and 280 may be designed and fabricated to increase the ESR of a coupled capacitor in order to reduce resonance.

Conductive network 260 includes microvias 261, 263, 265 and 267 coupled as shown to conductive traces 262, 264, 266 and 268 so as to descend through the layers and planes of package 200. An electrical signal passing through elements 261 through 268 returns to conductive plane 224 through microvia 269. Microvia 269 is coupled to conductive trace 270 of plane 224, which is in turn coupled to microvia 271. Microvia 271 is also coupled to conductive trace 272 of plane 226. Conductive trace 272 may extend into conductive plane 226 and be coupled to other planes within integrated circuit package 200 which eventually connect to other unshown circuitry.

Conductive network 280 includes elements 281 through 286 coupled as shown so as to descend through the layers and planes of package 200. Microvia 287 is coupled to conductive trace 286 to return network 280 to conductive plane 222. Conductive trace 288 of plane 222 is coupled to microvia 287 and to microvia 289. Microvia 289 is also coupled to conductive trace 290 of plane 224, which may in turn be coupled to other circuitry.

Conductive networks 260 and 280 may effectively increase the ESR of a capacitor coupled to conductive pads 240 and 250. The increased ESR may reduce resonance during operation of a system including package 200, and/or may allow the use of a capacitor having a lower ESR than would be required in the absence of networks 260 and 280.

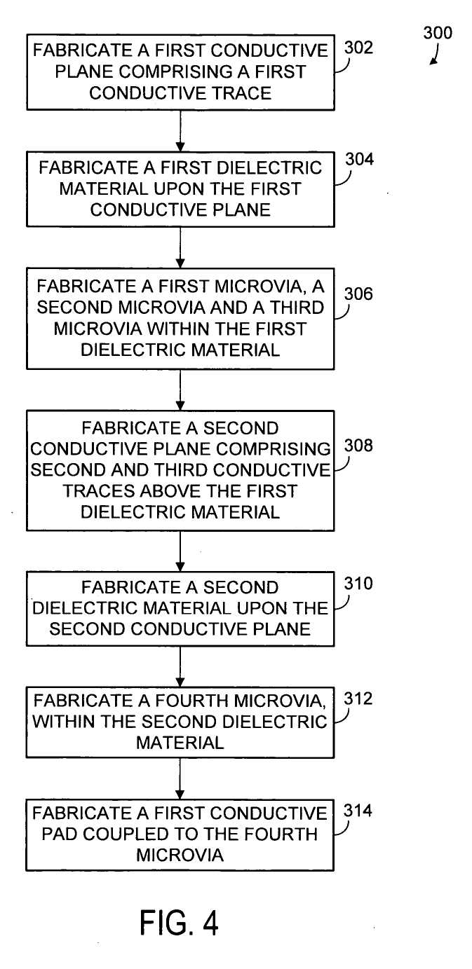

FIG. 4 is a flow diagram of a method to fabricate an apparatus according to some embodiments. Method 300 may be executed by any combination of hardware, software and/or firmware, and some or all of method 300 may be performed manually. Portions of method 300 may be performed by different entities. For example, method 300 may be performed by any combination of an integrated circuit manufacturer, a capacitor manufacturer, and a system integrator.

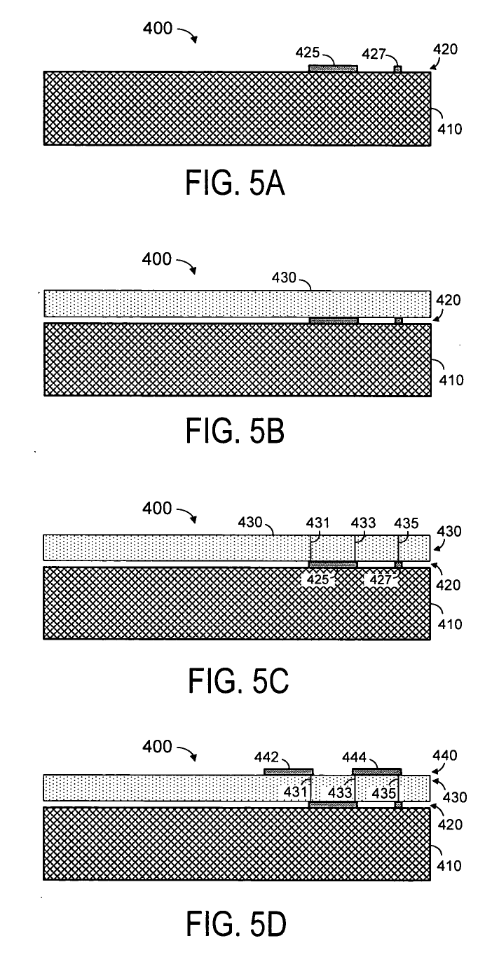

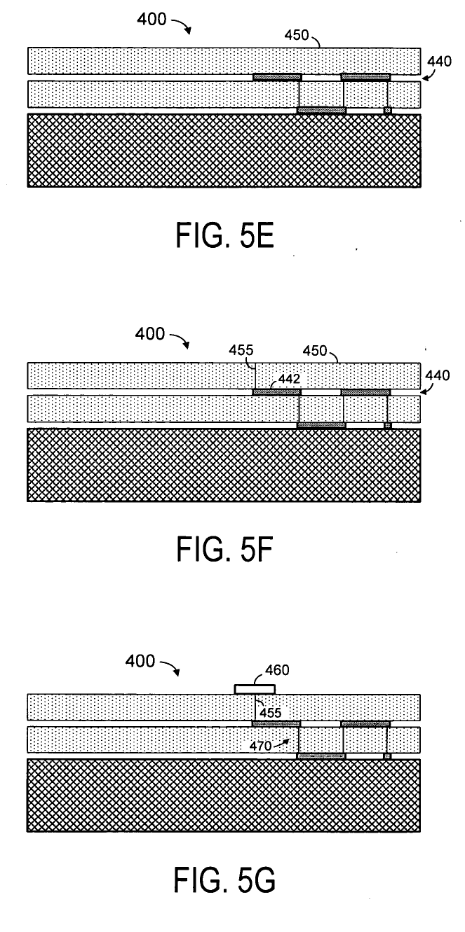

Initially, a first conductive plane is fabricated at 302. The first conductive plane includes a first conductive trace. FIG. 5A is a side cutaway view of core 410 and conductive plane 420 fabricated thereon in accordance with some embodiments of 302. Plane 420 may be fabricated using any suitable system that is or becomes known. Non-exhaustive examples include electroplating and photolithographic systems.

As shown, plane 420 includes conductive traces 425 and 427. Traces 425 and 427 may or may not be electrically coupled within plane 420. Moreover, conductive plane 420 may include other conductive traces, each of which may or may not be electrically coupled to traces 425 and/or 427. Plane 420 may include dielectric or other material in addition to conductive elements.

A first dielectric is fabricated upon the first conductive plane at 304. The dielectric material may be comprise a sheet of material that is simply laid upon the first conductive plane at 304, or may be fabricated thereon in any other manner. FIG. 5B shows layer of dielectric material 430 fabricated upon plane 420 according to some embodiments.

Next, at 306, a first, second and third microvia are fabricated within the first dielectric material. The first and second microvia are coupled to the first conductive trace. Microvias 431, 433 and 435 of FIG. 5C are fabricated according to some embodiments of 306. As shown, microvias 431 and 433 are coupled to trace 425. Microvia 435 is also coupled to trace 427. A microvia may be drilled into a layer of system 400 using a laser and/or may be fabricated using conventional photolithography.

A second conductive plane including second and third conductive traces is fabricated above the first dielectric material at 308. The second and third conductive traces are coupled to the first and second microvias, as illustrated by plane 440 and traces 442 and 444 of FIG. 5D. Trace 444 is also coupled to microvia 445.

A second dielectric material is fabricated upon the second conductive plane at 310, and a fourth microvia is fabricated within the second dielectric material at 312. FIG. 5E shows layer 450 of second dielectric material and FIG. 5F shows microvia 455 fabricated therein. Microvia 455 is coupled to conductive trace 442 of conductive plane 440.

At 314, a first conductive pad is fabricated. Conductive pad 460 is shown in FIG. 5G coupled to microvia 455 according to some embodiments of 314. Conductive pad 460 may be fabricated using any currently- or hereafter-known systems for fabricating electrical contacts. The resulting network shown in FIG. 5G may increase the effective ESR of a capacitor that is coupled to conductive pad 460. Moreover, the increase in ESR may be controlled by varying the dimensions, routing and/or composition of network 470.

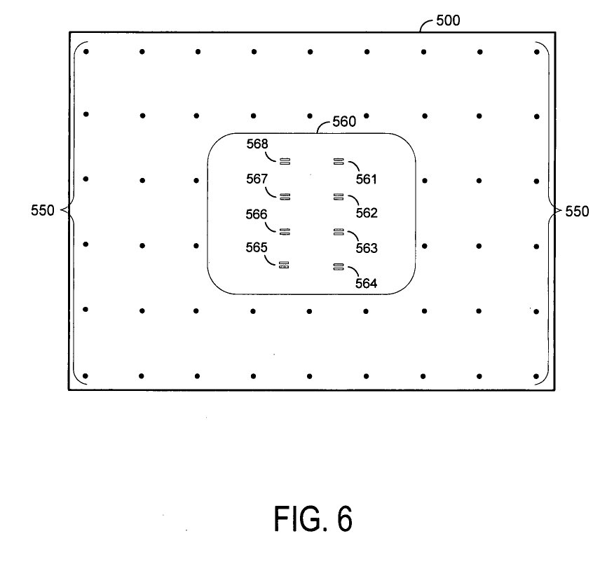

FIG. 6 is a bottom view of integrated circuit package 500 according to some embodiments. Integrated circuit package 500 may be similar to packages 100 and/or 200 described above, and may be fabricated according to method 300.

Pins 550 of package 500 are disposed around recess 560, and conductive pad sets 561 through 568 are disposed within recess 560. Each of conductive pad sets 561 through 568 comprises two conductive pads to receive a decoupling capacitor. The conductive pads of contact sets 561 through 568 may comprise any currently- or hereafter-known conductive contacts, including but not limited to gold and/or nickel-plated copper contacts fabricated upon integrated circuit package 500. Pad sets 561 through 568 may be recessed under, flush with, or extending above the illustrated surface of package 500.

According to some embodiments, pad sets 561 through 568 are coupled to a power delivery circuit of package 500. Decoupling capacitors may be mounted in recess 560 to reduce resonance between integrated circuit package 500 and a board such as motherboard on which integrated circuit package 500 is to be mounted.

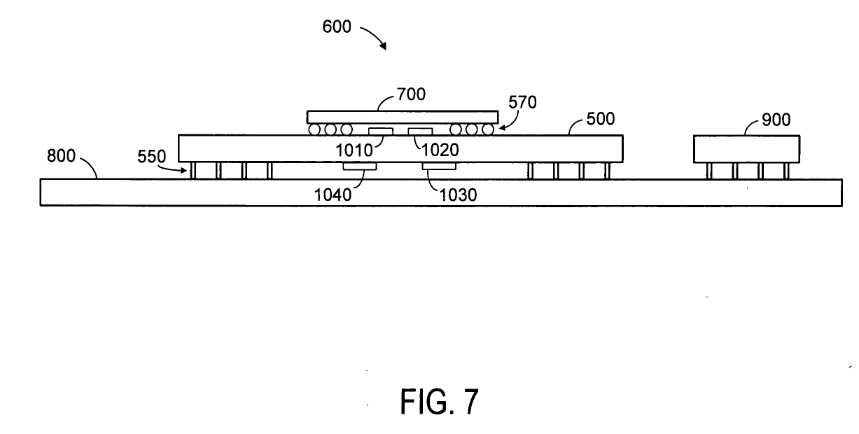

FIG. 7 is a side elevation of system 600 according to some embodiments. System 600 includes integrated circuit 700, package 500, motherboard 800 and memory 900. Integrated circuit 700 may be fabricated using any suitable substrate material and fabrication technique and may provide any functions to system 600. In some embodiments, integrated circuit 700 is a microprocessor chip having a silicon substrate. Package 500 is electrically coupled to circuit 700 by Controlled Collapse Chip Connect (C4) solder bumps 570. In some embodiments, package 500 is electrically coupled to circuit 700 via wire bonds.

Capacitors 1010 through 1040 are mounted on package 500. Terminals of capacitors 1010 through 1040 may be mounted using surface mount techniques on conductive pads of package 500. One or more of the conductive pads may be coupled to a network of microvias and conductive traces according to some embodiments. Capacitors 1010 through 1040 may be similar to or different from one another, and each may comprise two or more capacitor terminals.

Pins 550 couple package 500 to motherboard 800. In this regard, package 500 and pins 550 may comprise a grid array to interface with a socket (not shown) of motherboard 800. According to some embodiments, package 500 is a surface-mountable substrate such as an Organic Land Grid Array substrate that may be mounted directly on motherboard 800 or mounted on a pinned interposer which mates with a socket of motherboard 800. Packaging systems other than those mentioned above may be used in conjunction with some embodiments.

Integrated circuit 700 may communicate with memory 900 through package 500 and motherboard 800. Memory 900 may comprise any type of memory for storing data, including but not limited to a Single Data Rate Random Access Memory, a Double Data Rate Random Access Memory, or a Programmable Read Only Memory.

The several embodiments described herein are solely for the purpose of illustration. Embodiments may include any currently or hereafter-known versions of the elements described herein. Therefore, persons skilled in the art will recognize from this description that other embodiments may be practiced with various modifications and alterations.

What is claimed is:

1. An apparatus comprising:
a first conductive pad;
a first conductive plane;
first dielectric material disposed between the first conductive plane and the first conductive pad;
a second conductive plane;
second dielectric material disposed between the first conductive plane and the second conductive plane; and
a first conductive network comprising:
a first microvia within the first dielectric material and coupled to the first conductive pad;
a first conductive trace within the first conductive plane and coupled to the first microvia;
a second microvia within the second dielectric material and coupled to the first conductive trace;
a second conductive trace within the second conductive plane and coupled to the second microvia;
a third microvia within the second dielectric material and coupled to the second conductive trace;
a third conductive trace within the first conductive plane and coupled to the third microvia; and
a fourth microvia within the second dielectric material and coupled to the third conductive trace.

2. An apparatus according to claim 1, further comprising:
a second conductive pad, the first dielectric material disposed between the first conductive plane and the second conductive pad; and
a second conductive network comprising:
a fifth microvia within the first dielectric material and coupled to the second conductive pad;
a fourth conductive trace within the first conductive plane and coupled to the fifth microvia; and
a second microvia within the second dielectric material and coupled to the fourth conductive trace.

3. An apparatus according to claim 2, further comprising:
a capacitor having a first terminal and a second terminal,
wherein the first terminal is coupled to the first conductive pad, and
wherein the second terminal is coupled to the second conductive pad.

4. An apparatus according to claim 3, further comprising:
a third conductive pad,
wherein the capacitor further comprises a third terminal, and
wherein the third terminal is coupled to the third conductive pad.

5. An apparatus according to claim 3, further comprising:
an integrated circuit die comprising a circuit electrically coupled to the first conductive pad and to the second conductive pad.

6. An apparatus according to claim 1, the first network further comprising a fourth conductive trace within the second conductive plane and coupled to the fourth microvia.

7. A method comprising:
fabricating a first conductive plane comprising a first conductive trace;
fabricating a first dielectric material upon the first conductive plane;
fabricating a first microvia, a second microvia and a third microvia within the first dielectric material, the first microvia and the second microvia being coupled to the first conductive trace;
fabricating a second conductive plane above the first dielectric material, the second conductive plane comprising a second conductive trace and a third conductive trace, the second conductive trace being coupled to the first microvia and the third conductive trace being coupled to the second microvia and to the third microvia;
fabricating a second dielectric material upon the second conductive plane;
fabricating a fourth microvia within the second dielectric material, the fourth microvia being coupled to the second conductive trace; and
fabricating a first conductive pad coupled to the fourth microvia.

8. A method according to claim 7, further comprising:
fabricating a fifth microvia within the first dielectric material;
fabricating a sixth microvia within the second dielectric material; and
fabricating a second conductive pad coupled to the sixth microvia,
wherein the second conductive plane includes a fourth conductive trace, the fourth conductive trace being coupled to the fifth microvia and the sixth microvia.

9. A method according to claim 8, further comprising:
coupling a first terminal of a capacitor to the first conductive pad; and
coupling a second terminal of the capacitor to the second conductive pad.

10. A method according to claim 9, further comprising:
fabricating a third conductive pad electrically coupled to the first conductive pad; and
coupling a third terminal of the capacitor to the third conductive pad.

11. A method according to claim 9, further comprising:
electrically coupling a circuit of an integrated circuit die to the first conductive pad and to the second conductive pad.

12. A system comprising:
a microprocessor;
an integrated circuit package coupled to the microprocessor, the integrated circuit package comprising:
a first conductive pad;
a first conductive plane;
first dielectric material disposed between the first conductive plane and the first conductive pad;
a second conductive plane;
second dielectric material disposed between the first conductive plane and the second conductive plane; and
a first conductive network comprising:
a first microvia within the first dielectric material and coupled to the first conductive pad;
a first conductive trace within the first conductive plane and coupled to the first microvia;
a second microvia within the second dielectric material and coupled to the first conductive trace;
a second conductive trace within the second conductive plane and coupled to the second microvia;
a third microvia within the second dielectric material and coupled to the second conductive trace;
a third conductive trace within the first conductive plane and coupled to the third microvia; and
a fourth microvia within the second dielectric material and coupled to the third conductive trace.

13. A system according to claim 12, the integrated circuit package further comprising:
a second conductive pad, the first dielectric material disposed between the first conductive plane and the second conductive pad; and
a second conductive network comprising:
a fifth microvia within the first dielectric material and coupled to the second conductive pad;
a fourth conductive trace within the first conductive plane and coupled to the fifth microvia; and
a second microvia within the second dielectric material and coupled to the fourth conductive trace.

14. A system according to claim 13, further comprising:
a capacitor having a first terminal and a second terminal,
wherein the first terminal is coupled to the first conductive pad, and
wherein the second terminal is coupled to the second conductive pad.

15. A system according to claim 14, further comprising:
a third conductive pad,
wherein the capacitor further comprises a third terminal, and
wherein the third terminal is coupled to the third conductive pad.
